(19) United States
(12) Patent Application Publication
(10) Pub. No.: US 2025/0323434 A1
(43) Pub. Date: Oct. 16, 2025

(54) CONNECTING DEVICE FOR AN AUTOMATION PLATFORM AND AUTOMATION PLATFORM

(71) Applicant: Murrelektronik GmbH, Oppenweiler (DE)

(72) Inventors: Olaf Prein, Lügde-Rischenau (DE); Heiko Feisst, Schlierbach (DE); Tim Roolf, Backnang (DE)

(21) Appl. No.: 19/091,014

(22) Filed: Mar. 26, 2025

(30) Foreign Application Priority Data
Apr. 12, 2024 (DE) DE102024110294.2

(51) Int. Cl. H01R 12/70; H01R 9/26

(52) U.S. Cl. CPC H01R 12/7088; H01R 9/2675

(57) ABSTRACT

The invention relates to a connecting device (10) for an automation platform, comprising a contacting receiving element (12) which is configured to provide contacting with a contacting element (22) of a functional module (20) corresponding to the contacting receiving element (12) and to provide at least one of a main energy flow, an auxiliary energy flow and a data flow to the functional module (20) and a grounding receiving element (15) which is configured to provide grounding for the functional module.

The present invention relates to a connecting device for an automation platform, an automation platform with such a connecting device and a plant.

It is known from the prior art that modular automation solutions are used to supply electrical devices in an industrial plant with power via power lines and to control them via control lines, such as field bus lines. Modularity is often achieved by using individual, independent functional modules that can be individually configured and combined. This has the advantage that the automation solutions can be flexibly adapted to the respective requirements of the industrial plant, thus ensuring a high level of efficiency and cost-effectiveness.

The document US 2013/0342152 A1 discloses a multi-wave motor drive device in which at least one amplifier module, one control substrate and one power substrate are provided.

The documents WO 2012/000808 A1, WO 2023/088883 A1 and EP 2 728 673 B1 disclose further solutions of a generic nature.

A common problem with conventional solutions is that the assembly of functional modules of an automation platform can be complex and prone to errors. Therefore, one purpose of the present invention is to at least partially eliminate the disadvantages described above. In particular, one purpose of the present invention is to improve the connection of functional modules with a common connecting device.

### DISCLOSURE OF THE INVENTION

The subject of the invention is a connecting device with the features of claim 1, as well as an automation platform with the features of claim 11 and a plant with the features of claim 15. Further features and details of the invention can be found in the respective sub-claims, the description and the drawings. Features and details described in connection with the connecting device according to the invention naturally also apply in connection with the automation platform and the plant according to the invention, and vice versa, so that mutual reference is or can be made with regard to the disclosure of the individual aspects of the invention.

The invention relates in particular to a connecting device for an automation platform.

The connecting device according to the invention can comprise:
a contacting receiving element, also referred to as contact receiving element, that is configured to provide contact (contacting) with a contacting element, also referred to as contact element, of a functional module, also referred to as function module, that corresponds to the contacting receiving element and to provide at least one of a main energy flow, an auxiliary energy flow and a data flow to the functional module via this contact, and/or
an earthing receiving element, also referred to as grounding receiving element, that is configured to provide an earth connection, also referred to as grounding, for the functional module.

It is therefore optionally possible for the contacting receiving element to be designed to provide the contacting with the contacting element. The contacting element can be part of the functional module. Furthermore, the contacting element can be designed to correspond to the contacting receiving element. In the present context, “corresponding” means, in particular, that the two elements fit together, in particular functionally and/or spatially-physically, are compatible with each other, are shaped the same or complementary to each other and/or are designed to complement each other.

In addition, the contacting receiving element can optionally be designed to provide at least one of a main energy flow, an auxiliary energy flow and a data flow, i.e. a main energy flow and/or an auxiliary energy flow and/or a data flow, to the functional module via this contact. This preferably means that the contact can be designed as an electrical contact which electrically conducts the main energy flow and/or the auxiliary energy flow and/or the data flow and thus electrically connects the contacting receiving element to the contacting element for the transmission of the main energy flow and/or the auxiliary energy flow and/or the data flow.

The main energy flow may also be referred to as main power flow, and the auxiliary energy flow may also be referred to as auxiliary power flow.

Optionally, the contacting receiving element can be designed to provide the main energy flow to the functional module and/or via the contact. Alternatively, or additionally, the contacting receiving element can be designed to provide the auxiliary energy flow to the functional module and/or via the contact. The main and/or auxiliary energy flow can be primarily intended for the energy supply of the functional module and/or at least one further component, for example in an industrial plant. In this case, the main energy flow can be greater in terms of its voltage level, preferably at least two, four or ten times as large as the auxiliary energy flow.

Alternatively, or additionally, the contacting receiving element can be designed to provide the data flow to the functional module and/or via the contacting. In contrast to the main and/or auxiliary energy flow, the data flow can be provided not primarily for energy supply, but for data exchange. If several of the main energy flow and the auxiliary energy flow and the data flow are provided, different contact points can also be provided for them.

The connecting device and/or the automation platform and/or a respective automation platform according to the invention can advantageously serve for automation in an industrial plant such as an automation plant and/or the industrial plant according to the invention. Accordingly, the energy supply via the main and/or auxiliary energy flow can be used to supply energy to at least one component in this plant/system and/or to provide at least one process and preferably an automation process.

An automation platform for which the connecting device according to the invention is designed and constructed can be understood as hardware, possibly with associated software, in order to automate certain processes in an electrical plant/system. For example, motors, preferably servomotors, are controlled in this way to move a robot arm or control a conveyor belt. The connecting device can be at least part of the automation platform, in order to connect one or more functional modules to it and/or to connect them to each other, and in this way to provide various modular functions for the automation, such as controlling the motors. This can have the advantage that the connecting device with the functional modules is able to connect and/or control and/or evaluate a multiplicity of devices and components in an electrical plant/system in order to ensure smooth and efficient automation.

The modularity can be achieved by the functional modules being designed as individual modules, in particular modules that are independent of one another, each with its own module housing and electronics that allow the modules to be configured individually and combined functionally with further functional modules. The functional modules can also have data and/or energy supply interfaces to one another and/or to devices and/or components of the electrical system. For example, it is possible that at least one of the functional modules connected to the connecting device is able to establish a wired and/or wireless connection to a device and/or component to be controlled. Also, at least one of the functional modules connected to the connecting device can be designed to provide a power supply for a device and/or component to be controlled and/or the other connected functional modules.

In the connecting device according to the invention, at least one contacting receiving element can initially be provided, which is designed to provide a contact with a (respective) contacting element of a functional module corresponding to the contacting receiving element and to provide at least one of a main energy flow, an auxiliary energy flow and/or a data flow to the functional module via this contact. In the present case, a contact means, in particular, the provision and/or establishment of an electrical connection, in particular a signal and/or power connection. In the present case, corresponding means, in particular, that the two elements match each other, in particular functionally and/or spatially-physically, are compatible with each other, are shaped and/or designed to be the same or complementary to each other. The at least one contacting receiving element can comprise a first and/or second and/or third contacting receiving element. The first contacting receiving element can be designed to provide a contact with a first contacting element of the functional module that corresponds to the first contacting receiving element and to provide a main energy flow to the functional module via this. The second contacting receiving element can be designed to provide a contact with a second contacting element of the functional module corresponding to the second contacting receiving element and to provide an auxiliary energy flow to the functional module via this. The third contacting receiving element can be designed to provide a contact with a third contacting element of the functional module corresponding to the third contacting receiving element and to provide a data flow to the functional module via this.

In this context, the term “receiving” in the case of the contacting receiving element, also referred to as contacting-incorporating element, serves in particular initially to conceptually distinguish these elements from the contacting element of the functional module corresponding thereto and does not necessarily comprise a physical incorporation of the contacting element, but rather the contacting receiving element merely establishes a contact with the contacting element of the functional module by means of contacting and/or touching.

However, it may also be provided that the contacting receiving element comprises one or more receiving devices or arrangements that are designed to physically receive the contacting element, in particular to engage with it, lock into place and/or interlock. In particular, the contacting receiving element can have a plug receiver and the contacting element can have a plug corresponding to it, or vice versa.

In particular, it can be provided that the contacting receiving element comprises a pin-socket contact. A pin-socket contact is a type of contact in which one or more pins and/or rods, which can also be referred to as a male contact, are inserted into and engage with one or more corresponding sockets and/or plug receptacles, which can also be referred to as a female contact, for example by static friction. In particular, the contacting receiving element has one or more sockets and/or receptacles for receiving one or more pins and/or rods, and the contacting element has one or more pins and/or rods that are incorporated/received in the socket(s) and/or receptacle(s) of the contacting receiving element.

Alternatively or additionally, it may be provided that the contacting receiving element, also referred to as contact-incorporation element, comprises a spring contact. A spring contact is a type of contact in which at least one of the contacting receiving element and the contacting element is designed as a spring, at least in sections. The spring can be prestressed in a certain direction, in particular in an insertion direction, as will be described in more detail below. In addition or alternatively, the contacting element of the functional module can comprise a spring contact. In this case, the contacting receiving element can also be designed as a surface contact or, alternatively, also as a spring contact, which in each case interacts with a spring contact of the functional module or vice versa. In this case, the spring contact can be designed in particular as a spring clip. A spring clip is, for example, a clip composed or formed from two spring elements formed clamp, in which the spring elements are arranged opposite each other, so that a space in between is tapered inwards by the pretension of the spring elements and this space is widened by an insertion movement, for example in the insertion direction, so that the contacting element of the functional module can be received and securely held in it.

Alternatively, or additionally, it may be provided that the contacting receiving element comprises a surface contact. A surface contact can be designed as a flat element and, for example, interact with a corresponding surface or a surface receiver, which overlaps at least in sections with the surface contact and thus establishes a contact. Alternatively, or additionally, the surface contact can also interact with a spring contact and pick it up or make contact with it. In particular, means or elements can be provided both on the contacting receiving element and on the corresponding contacting element that enable, support and/or provide a pin-socket contact and/or a spring contact and/or a surface contact.

A grounding receiving element, also referred to as earthing receiving element, may be provided that is designed to provide grounding, also referred to as earthing, for the functional module. The grounding receiving element provides a grounding function for the functional module, for example because it establishes or provides a conductive contact between the functional module and a grounding of the connecting device or the automation platform. In particular, the grounding receiving element provides equipotential bonding from the functional module to ground. It should also be noted with regard to the grounding receiving element and in particular also with regard to the designs of the grounding receiving element and, if applicable, corresponding elements on the functional module, which will be explained in more detail below, that the term “receiving” is also used in this context to distinguish this element from a corresponding element of the functional module and does not necessarily include a physical receiving/incorporation, but rather the grounding receiving element merely establishes grounding for the functional module by means of contact and/or touching.

However, it may also be envisaged that the grounding receiving element comprises one or more receiving devices or arrangements that are designed to physically receive corresponding elements of the functional module, in particular to engage with them, lock into place and/or interlock, as will be described in more detail below. In this case, the grounding receiving element can be designed to be spatially and/or technologically separated or separated from the contacting receiving element, but it does not have to be, as will also be explained in the further course. The solution according to the invention provides a particularly reliable grounding contact for a functional module of an automation platform.

A further advantage may be that the grounding receiving element has a form-fitting receiving element, the form-fitting receiving element being designed to engage in a form-fitting manner with a corresponding form-fitting element of the functional module in order to provide grounding. In this case, the form-fitting receiving element and the form-fitting element can interact or engage with each other in such a way that movement of the two elements in relation to each other is impeded or prevented in at least one direction. This makes it possible to achieve a particularly secure grounding.

According to an advantageous further development of the invention, it can be provided that the grounding receiving element has a fastening receiving element, wherein the fastening receiving element is designed to be fastened to a corresponding fastening element of the functional module in order to provide grounding. In particular, the fastening receiving element and/or the fastening element can interact in such a way that movement of the two elements with respect to one another is impeded or prevented in at least one direction, in particular in all directions. In this case, the fastening receiving element and/or the fastening element can be designed, for example, as a latching element so that the two elements engage or latch into one another in such a way that it is not possible to release them without a tool. In particular, the fastening receiving element and/or the fastening element can be designed as a hole and screw and/or rivet, which can be released from one another non-destructively or destructively. For example, a hole can be provided on the fastening receiving element and/or on the fastening element, through which a fastening means, such as a screw or a rivet, is passed and, if necessary, with a further fastening means, such as a nut, or by crimping, the fastening receiving element and the fastening element are fastened to one another. This enables a particularly secure grounding.

It is advantageous that the invention can provide that the grounding receiving element has a grounding surface receiving element, wherein the grounding surface receiving element is designed to engage over a flat area with a corresponding grounding surface element of the functional module in order to provide grounding. In this case, the grounding surface receiving element can be designed as a flat element and, for example, can interact with the surface or surface receiving element corresponding thereto, so that the latter overlaps at least in sections with the area of the grounding surface receiving element and thus provides a grounding. This provides a particularly simple grounding.

Furthermore, the invention may provide that the grounding receiving element has a grounding band receiving element, wherein the grounding band receiving element is designed to engage with a corresponding grounding band element of the functional module in order to provide grounding. In this case, grounding is ensured by a grounding band (also referred to as strip) which is connected between the grounding band receiving element and the grounding band element and provides equipotential bonding via this. This enables a particularly secure grounding.

Optionally, the grounding receiving element can be provided with a grounding cable receiving element, wherein the grounding cable receiving element is designed to engage with a corresponding grounding cable element of the functional module in order to provide grounding. In this case, grounding is ensured by a grounding cable that is connected between the grounding band receiving element and the grounding band element and provides equipotential bonding. This enables a particularly secure grounding.

Optionally, it may be provided that the main energy flow comprises an AC voltage of up to 1000 volts and/or a DC voltage of up to 1500 volts and/or an AC voltage in the range of 70 volts to 1000 volts and/or a DC voltage in the range of 130 volts to 1500 volts, and preferably an alternating voltage of essentially 400 volts or a direct voltage in the range of 650 V to 700 V.

Alternatively or additionally, it may be provided that the auxiliary energy flow comprises an alternating voltage of up to 50 volts and/or a direct voltage of up to 120 volts and/or an alternating voltage in the range from 0.01 volt to 50 volts and/or a direct voltage in the range from 0.01 volt to 120 volts, and preferably a DC voltage of essentially 24 V or 48 V.

In particular, it may be provided that the data flow is designed to transmit data and preferably field bus signals, preferably for communication with at least one of the devices to be controlled.

According to an advantageous further development of the invention, it may be provided that the connecting device comprises a further, at least second, contacting receiving element which is designed to provide a contacting with a further contacting element of the functional module corresponding to the further contacting receiving element and to provide at least one further of a main energy flow, auxiliary energy flow and/or data flow to the functional module via this contact.

Optionally, it can be provided that the first contacting receiving element is arranged in a first plane and the further second contacting receiving element is arranged in a second plane, which is angled with respect to the first plane. An angle can thus be formed between the first plane of the connecting device and the second plane of the connecting device. In particular, the angle between the two planes can be greater than 15°, greater than 30°, greater than 45°, greater than 60°, greater than 75°, greater than 80° or greater than 85°. Alternatively, or additionally, the angle between the two planes of the connecting device can be less than 165°, less than 150°, less than 135°, less than 120°, less than 105°, less than 100° or less than 95°. In particular, the angle is between 85° and 95° and is further more particularly approximately, substantially or exactly 90°. In particular, the first plane in which or along which the first contacting receiving element is arranged is approximately, essentially or exactly parallel to a floor in a plane and the second plane in which or along which the second contacting receiving element is arranged is approximately, essentially or exactly perpendicular to a floor in a plane. This makes it possible to connect a functional module in two different planes and, in particular, to securely fasten it in order to provide one or more of a main energy flow, an auxiliary energy flow and/or a data flow in the two planes to the functional module.

A further advantage may be that the first plane and the second plane of the connecting device are arranged in relation to one another in such a way that they allow the functional module to be inserted in an insertion direction that is essentially perpendicular to one of the first plane and the second plane and wherein the grounding receiving element is arranged and designed in such a way that it provides grounding in the insertion direction. As stated above, the first and second planes can be arranged approximately, essentially or exactly at a right angle to each other. It can be provided that the functional module is guided in an insertion direction to the connecting device, which is approximately, essentially or exactly perpendicular to the first plane and which is approximately, essentially or exactly parallel to the second plane.

Furthermore, it may be provided within the scope of the invention that the grounding receiving element is arranged on the contacting receiving element and the connecting device comprises a further grounding receiving element, which is arranged on the further, second contacting receiving element. In particular, the first contacting receiving element can thus have the first grounding receiving element and the second contacting receiving element can have a further, second grounding-receiving element. In this case, the two grounding receiving elements can be designed differently or distinctively from one another. In particular, the first grounding receiving element can comprise one or more of a form-fitting receiving element, a fastening receiving element, a grounding surface receiving element, a grounding band receiving element and a grounding cable receiving element, and the second grounding receiving element can comprise one or more other of a form-fitting receiving element, a fastening receiving element, a grounding surface receiving element, a grounding band receiving element and a grounding cable receiving element. This allows the positive effects of the respective grounding connection types to be synergistically combined, thus producing a particularly secure grounding that is also redundant and fail-safe.

The invention also includes an automation platform comprising a connecting device according to one or more of the previously described embodiments, as well as at least one functional module. In particular, the automation platform can have more than one functional module, for example two, three or more, of which at least one functional module is connected and/or can be connected to the automation platform via a connecting device according to one or more of the previously described embodiments.

Optionally, it may be provided that the automation platform has a further connecting device according to one or more of the previously described embodiments, wherein each of the at least two connecting devices is connectable to at least one functional module, wherein the connecting devices are designed to provide at least one of the main energy flow, the auxiliary energy flow and/or the data flow to the functional modules. In particular, each of the functional modules can provide a different function for the automation platform. In particular, a first connecting device can be provided according to one or more of the previously described embodiments, which can be connected and/or is connected to a first functional module, and a second connecting device can be provided according to one or more of the previously described embodiments, which can be connected and/or is connected to a second functional module, in particular a functional module that is different from the first functional module. In this context, the first functional module can provide a first function within the automation platform and the second functional module can provide a second function which is different from the first function.

According to a further advantage, it can be provided that the connecting devices are arranged with respect to one another and designed in such a way that they provide at least one of the main energy flow, the auxiliary energy flow and/or the data flow serially to the functional modules. In particular, the functional modules are also arranged and designed with respect to one another such that they provide at least one of the main energy flow, the auxiliary energy flow and/or the data flow serially to other functional modules. In other words, the first contacting receiving elements and/or the second contacting receiving elements and/or the main energy flow, auxiliary energy flow and/or data flow applied thereto are interconnected such that that they are connected to one another in series, that is to say serially, so that in each case at least one main energy flow, one auxiliary energy flow and/or one data flow is provided, to or from which the contacting receiving elements are connected and from which the contacting receiving elements are supplied. The contacting receiving elements are in this case connected in particular in such a way that they can receive and forward the main energy flow, the auxiliary energy flow and/or the data flow.

Advantageously, in the invention, the automation platform may further comprise a bridge element, which is connected to one of the connecting devices and which is designed to receive at least one of the main energy flow, the auxiliary energy flow and/or the data flow and to provide it to a further connecting device. Such a bridge element, which can also be referred to as an empty element or a dummy element, can be received in one or more contacting receiving elements of one or more connecting devices and provide a forwarding functionality, in particular when no functional module is received in the respective connecting device. In particular, the bridging element is designed to receive one or more of the main energy flow, the auxiliary energy flow and/or the data flow in a state received by a connecting device and to forward it to a further connecting device, in particular to loop through and/or to bridge, so that one or more of the main energy flow, the auxiliary energy flow and/or the data flow, in particular in the case of a serial connection, is not interrupted. In addition, the bridging element can also protect the first and/or second contacting receiving element from external influences, such as dust or dirt.

A system with at least two (or at least four or at least six) automation platforms is also optionally protected, each of which can optionally be designed as the aforementioned automation platform according to the invention. In this case, the automation platforms can each be designed as a decentralized automation platform and correspondingly designed to provide partial automation functions and in particular each a part of an overall control for the automation of an industrial plant. In this case, the automation platforms can be arranged decentrally in the field of the plant, in particular in order to jointly replace a function of a central control cabinet. Furthermore, the automation platforms can be connected to one another and/or to a central controller via an industrial communication system and/or a field bus.

The invention also relates to a system, also referred to as plant and preferably an industrial plant, with at least two (or at least four or at least six) automation platforms, which can optionally be designed as the invention-based automation platform. In this case, the automation platforms can each be designed as a decentralized automation platform and can be designed accordingly to provide partial automation functions and, in particular, each a part of an overall control system for the automation of the industrial plant. In this case, the automation platforms can be arranged decentrally in the field of the plant, in particular in order to jointly replace a function of a central control cabinet. Furthermore, the automation platforms can be connected to each other and/or to a central controller via an industrial communication system and/or via a field bus. The automation platforms can thus be distributed in the field of the plant and used together to take over the function of the usually provided central control cabinet. This can have the advantage that the plant can be designed more flexibly and, in particular, that the automation functions can be easily adapted when the plant is expanded or converted. In addition, the decentralized arrangement of the automation platforms can achieve a higher level of reliability, since the entire automation of the system is not affected if one platform fails. It is also possible that the system can be made more cost-efficient by using the automation platforms according to the invention, since the acquisition costs for a central control cabinet are eliminated and the decentralized arrangement of the platforms enables a reduction in cabling costs.

The respective automation platform according to the system and/or the plant according to the invention can optionally comprise: a connecting device and/or at least one functional module, wherein the (respective) connecting device comprises:
a contacting receiving element designed to provide a contact with a contacting element of a/the functional module corresponding to the contacting receiving element and to provide at least one of a main energy flow, an auxiliary energy flow and a data flow to the functional module via it, and/or
a grounding receiving element designed to provide grounding for the functional module.

The automation platforms can each be equipped with their own power supply and/or a cloud-based platform for remote monitoring and control and/or an integrated diagnostic function to ensure higher availability and reliability, easy troubleshooting, and automatic error detection and correction. This may have the advantage that the automation platforms can be operated independently of the site's power supply and are therefore suitable for use in different environments. It is also possible that the cloud-based platform for remote monitoring and control allows the automation platforms to be monitored and controlled from a remote location, which increases ease of use. The integrated diagnostic function can help to ensure that possible faults can be quickly and easily detected and rectified, thus facilitating the maintenance and servicing of the automation platforms and reducing operating costs.

Another advantage of the automation platform according to the invention is the possibility to create and use a digital twin of the industrial plant. This is, in particular, a virtual representation of the plant that is created based on real-time data and simulations. The digital twin can be used to optimize the plant by simulating various scenarios and amendments before they are implemented in the real plant. This can help to increase the efficiency and productivity of the plant while minimizing the risk of faults and failures. The digital twin can also be used to optimize the maintenance and servicing of the plant by identifying potential problems at an early stage and rectifying them before they lead to failures.

The automation platform according to the invention or the respective automation platform of a plant according to the invention can be designed to accommodate several functional modules in order to supply them with energy via the main and/or auxiliary energy flow and/or to control them via the data flow and/or to enable a data exchange for them via the data flow.

The functional modules can provide various automation functions, in particular in the form of partial automation functions, for the automation of the industrial plant. The automation functions can include at least two of the following:
motor control;
control and/or energy supply of a motor control, which is preferably provided outside the automation platform in the vicinity of the motor;
A control and/or power supply for an actuator, such as a motor, a valve, a stepper motor, a linear drive, a piezo actuator, a solenoid actuator, a hydraulic cylinder, a pneumatic cylinder, a flap drive, a gripper arm, a robot arm, a turntable, a conveyor belt, a crane arm, a pivot arm, a drill, a cutter, a welding device, a cutting or engraving laser, a vibration motor, a loudspeaker, an actuator in medical technology, an actuator in the automotive industry, an actuator in the aerospace industry, an actuator in robotics, an actuator in the electronics or semiconductor industry, an actuator in the food or packaging industry and/or an actuator in the textile or paper industry;
a read-out and/or control and/or power supply of a sensor, preferably a proximity sensor and/or a light barrier.

Furthermore, the functional modules can also include a safety module for monitoring and safeguarding processes and/or an industrial PC and/or a field bus module.

Further advantages, features and details of the invention will become apparent from the following description, in which, with reference to the drawings, examples of the invention are described in detail. The features mentioned in the claims and in the description may be individually or in any combination essential to the invention. The following show:

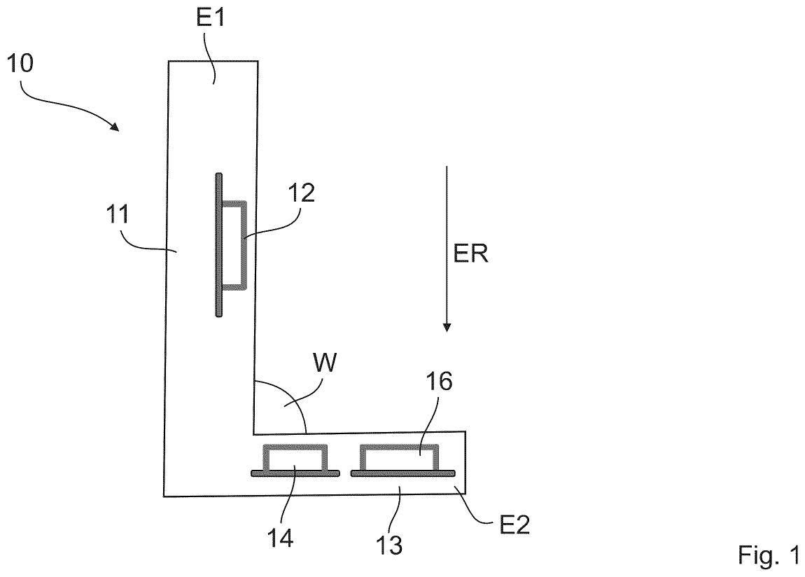

FIG. 1 a perspective view of a connecting device according to embodiments of the invention.

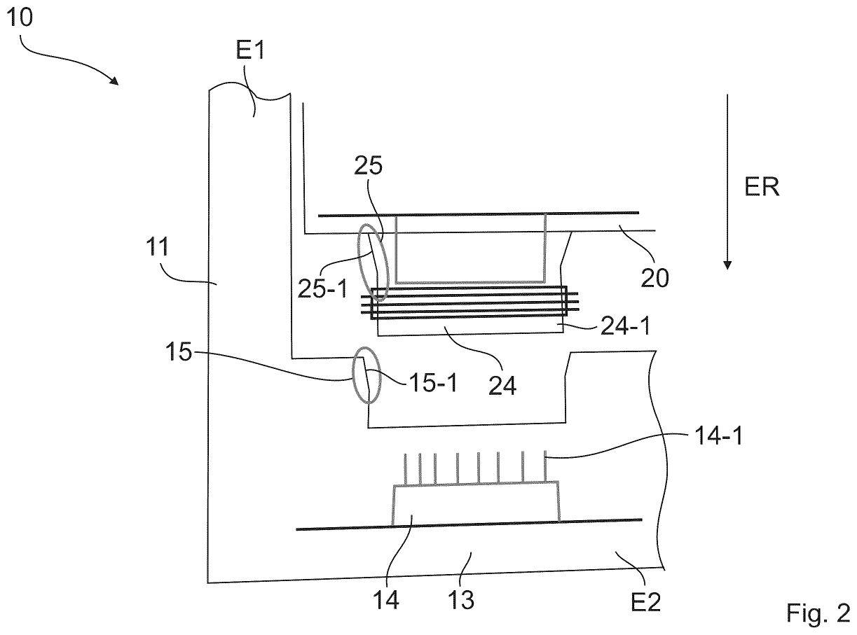

FIG. 2 a perspective view of a connecting device according to further embodiments of the invention

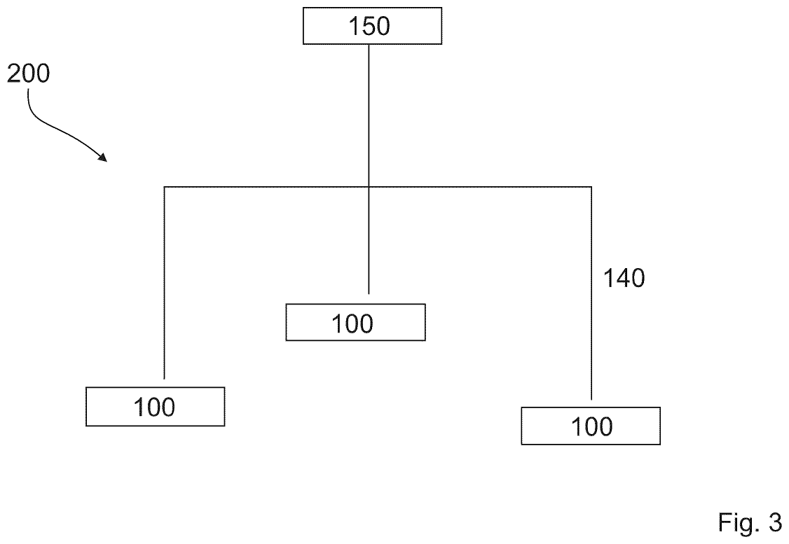

FIG. 3 a schematic representation of an industrial plant.

In the following figures, the identical reference signs are used for the same technical features, even for different examples.

FIG. 1 illustrates a perspective view of a connecting device 10 according to examples of the invention.

The connecting device 10 is used to connect one or more functional modules to an automation platform, which is not shown here in detail. In particular, a plurality of such connecting devices as are shown in FIG. 1 may be provided, which are in particular connected to one another in series. The automation platform may, for example, comprise a plurality of connecting devices and optionally one or more functional modules.

For this purpose, the connecting device 10 firstly comprises a first contacting receiving element 12, which is arranged in a first plane E1 and is designed to provide a first contact with a first contacting element, corresponding to the first contacting receiving element 12, of a functional module. The connecting device 10 can also include a second contacting receiving element 14, which is arranged in a second plane E2 and is designed to provide a second contact with a second contacting element of the functional module corresponding to the second contacting receiving element 14. In this FIG. 1, a further optional third contacting receiving element 16 is also shown, which is likewise arranged in the second plane E2.

The first plane E1 is formed at an angle to the second plane E2. In particular, the first plane E1 and the second plane E2 span an angle W between them, which is essentially 90°. As can be seen in particular in FIG. 1, the first contacting receiving element 12 is located in a first limb 11 and the second contacting receiving element 14 and the third contacting receiving element 16 are located in a second limb 13 of the connecting device 10, the two limbs likewise being arranged essentially perpendicular to one another, with a right-angle W between the two limbs. In other words, the two legs 11 and 13 are arranged in an L-shape in relation to one another and the connecting device 10 is essentially L-shaped.

The first contacting receiving element 12 is designed to provide one of a main energy flow, an auxiliary energy flow and a data flow to the functional module via the first contacting element, the second contacting receiving element 14 is designed to provide a further one of a main energy flow, an auxiliary energy flow and a data flow to the functional module via the second contacting element. In particular, the third contacting receiving element 16 is designed to provide an even further of a main energy flow, an auxiliary energy flow and a data flow via the first contacting element to the functional module. For example, the first contacting receiving element 12 provides a main energy flow, the second contacting receiving element 14 provides an auxiliary energy flow and the third contacting receiving element 16 provides a data flow via corresponding contacts to the functional module.

The main energy flow can comprise an AC voltage of up to 1000 volts and/or a DC voltage of up to 1500 volts and/or an AC voltage in the range from 70 volts to 1000 volts and/or a DC voltage in the range from 130 volts to 1500 volts, and preferably an AC voltage of substantially 400 volts or a DC voltage in the range of 650 V to 700 V. Likewise, the auxiliary energy flow can comprise an alternating voltage of up to 50 volts and/or a direct voltage of up to 120 volts and/or an alternating voltage in the range of 0.01 volts to 50 volts and/or a direct voltage in the range of 0.01 volts to 120 volts, and preferably a direct voltage of essentially 24 V or 48 V.

The contact between the respective contacting receiving element and the corresponding contacting element can be designed, for example, as a pin-socket contact, as a spring contact, in particular as a spring clip, and/or as a surface contact, and in particular also include combinations thereof. In particular, the contact between the first contacting receiving element 12 and the corresponding contacting element of the functional module is designed differently from the contact between the second contacting receiving element 14 and the corresponding contacting element of the functional module, or the two types of contact are different.

The functional module not shown here in FIG. 1 can be inserted in particular in the insertion direction ER indicated by the arrow, which is essentially parallel to the first plane E1 and essentially perpendicular to the second plane E2, in order to contact the first contacting receiving element 12, the second contacting receiving element 14 and optionally the third contacting receiving element 16, as will now be described in connection with the further figures.

The connecting device 10 also includes a grounding receiving element 15, not shown in detail in this figure, which is designed to provide grounding for the functional module, as will be explained in detail in connection with the following FIG. 2. In particular, the grounding receiving element can be configured as a form-locking (also referred to as form-fit) receiving element, as a fastening receiving element, as a grounding surface receiving element, as a grounding band receiving element and/or as a grounding cable receiving element, which engages and/or interacts with a corresponding element on the functional module in order to thereby provide grounding from or to the functional module.

FIG. 2 illustrates a perspective view of a connecting device 10 according to further embodiments of the invention.

As shown in detail in FIG. 2, the connecting device has a grounding receiving element 15 that provides grounding from or to the functional module 20, which is also shown here. The grounding receiving element 15 is shown here in such a way that it has a form-fitting receiving element 15-1 or is configured as such. The functional module 20 has a grounding/earthing element 25 corresponding to the grounding/earthing receiving element 15 and is shown here as an example as a form-fitting element 25-1, which engages in a form-fitting manner with the form-fitting receiving element 15-1. As an example, the grounding/earthing element 15 is shown here arranged on the second contacting receiving element 14. However, it is understood that, alternatively or additionally, a grounding element 15 can also be arranged on the first contacting receiving element and/or on the third contacting receiving element, as shown in FIG. 1.

FIG. 2 also shows in detail a type of contact between the second contacting receiving element 14 and the corresponding contacting element 24 of the functional module 20. This is shown here as an example of a pin-socket contact, with the second contacting receiving element 14 having one or several pin contacts 14-1 and the corresponding contacting element 24 has one or several socket contacts 24-1 that are designed to receive the pin contacts 14-1 and thus establish a contact between the functional module 20 and the connecting device 10.

FIG. 3 schematically shows an industrial plant 200 having at least two automation platforms 100. In this case, the automation platforms 100 can each be designed as a decentralized automation platform 100 and can be designed accordingly to provide in each case partial automation functions and in particular in each case a part of an overall control system for the automation of the industrial plant 200. For this purpose, the automation platforms 100 can be arranged decentrally in the field of the plant 200, in particular in order to jointly replace a function of a central control cabinet, the automation platforms 100 being connected to one another and/or to a central controller 150 via a field bus 140.

The above description of the embodiments describes the present invention exclusively in the context of examples. Of course, individual features of the embodiments can be freely combined with each other, provided that this is technically reasonable, without leaving the scope of the present invention.

### LIST OF REFERENCE SIGNS

10 connecting device
11 first leg
12 first contacting receiving element
13 second leg
14-1 pin contact
15 grounding receiving element
15-1 form-fit receiving element, form-locking receiving element
16 third contacting receiving element
20 functional module
22 first contacting element
24-1 socket contact-making
25 grounding element
25-1 form-fit element, form-locking element
E1 first level, first plane
E2 second level, second plane
ER insertion direction
W Angle

1. Connecting device for an automation platform, comprising:
a contacting receiving element which is configured to provide contacting with a contacting element of a functional module corresponding to the contacting receiving element and, via this, to provide at least one of a main energy flow, an auxiliary energy flow and a data flow to the functional module; and
a grounding receiving element, which is configured to provide grounding for the functional module.

2. Connecting device according to claim 1,
characterized in that
the grounding receiving element has a form-locking receiving element, the form-locking receiving element being configured to engage positively with a corresponding form-locking element of the functional module in order thereby to provide grounding.

3. Connecting device according to claim 1,
characterized in that
the grounding receiving element comprises a fastening receiving element, the fastening receiving element being configured to be fastened to a corresponding fastening element of the functional module in order thereby to provide grounding.

4. Connecting device according to claim 1,
characterized in that
the grounding receiving element comprises a grounding surface receiving element, the grounding surface receiving element being configured to flatly engage with a corresponding grounding surface element of the functional module in order thereby to provide grounding.

5. Connecting device according to claim 1,
characterized in that
the grounding receiving element comprises a grounding strap receiving element, the grounding strap receiving element being configured to engage with a corresponding grounding strap element of the functional module in order thereby to provide grounding.

6. Connecting device according to claim 1,
characterized in that
the grounding receiving element comprises a grounding cable receiving element, the grounding cable receiving element being configured to engage with a corresponding grounding cable element of the functional module in order thereby to provide grounding.

7. Connecting device according to claim 1,
characterized in that
the main energy flow comprises an alternating voltage of up to 1000 volts and/or a direct voltage of up to 1500 volts and/or an alternating voltage in the range from 70volts to 1000 volts and/or a direct voltage in the range from 130 volts to 1500 volts, and/or
that the auxiliary energy flow comprises an AC voltage of up to 50 volts and/or a DC voltage of up to 120 volts and/or an AC voltage in the range from 0.01 volts to 50 volts and/or a DC voltage in the range from 0.01 volts to 120 volts.

8. Connecting device according to claim 1,
characterized in that
the connecting device comprises a further contacting receiving element which is configured to provide contacting with a further contacting element of the functional module corresponding to the further contacting receiving element and to provide, via this, at least one further of a main energy flow, an auxiliary energy flow and a data flow to the functional module.

9. Connecting device according to claim 8,
characterized in that
the contacting receiving element is arranged in a first plane and the further contacting receiving element is arranged in a second plane, which is angled to the first plane.

10. Connecting device according to claim 8,
characterized in that
the grounding receiving element is arranged on the contacting receiving element and the connecting device comprises a further grounding receiving element which is arranged on the further contacting receiving element.

11. An automation platform, comprising:
a connecting device comprising:
a contacting receiving element which is configured to provide contacting with a contacting element of a functional module corresponding to the contacting receiving element and, via this, to provide at least one of a main energy flow, an auxiliary energy flow and a data flow to the functional module, and
a grounding receiving element, which is configured to provide grounding for the functional module; and
at least one functional module.

12. The automation platform according to claim 11, comprising a further connecting device, wherein each of the connecting devices is connectable to at least one functional module each, wherein the connecting devices are adapted to provide at least one of the main energy flow, the auxiliary energy flow and the data flow to the functional modules.

13. Automation platform according to claim 12,
characterized in that
the connecting devices are arranged and configured in such a way that they provide at least one of the main energy flow, the auxiliary energy flow and/or the data flow serially to the functional modules.

14. Automation platform according to claim 11,
further comprising a bridge element which is connected to one of the connecting devices and which is adapted to receive at least one of the main energy flow, the auxiliary energy flow and the data flow and to provide it to a further connecting device.

15. An industrial plant with at least two automation platforms,
each comprising a connecting device and at least one functional module, wherein the connecting device comprises:
a contacting receiving element which is configured to provide contacting with a contacting element of the functional module corresponding to the contacting receiving element and, via this, to provide at least one of a main energy flow, an auxiliary energy flow and a data flow to the functional module, and
a grounding receiving element which is configured to provide grounding for the functional module
characterized in that
the automation platforms are each configured as a decentralized automation platform and are correspondingly configured to provide partial automation functions in each case and, the automation platforms being arranged decentrally in a field of the plant, the automation platforms being connected to one another and/or to a central control system via a field bus.

16. The connecting device of claim 15 wherein the automation platforms are each configured in each case to provide a part of an overall control for the automation of the industrial plant.

17. The connecting device of claim 15 wherein the automation platforms are arranged decentrally in the field of the plant in order to jointly replace a function of a central control cabinet.

18. The connecting device of claim 7 further comprising at least one of:
wherein the alternating voltage is 400 volts;
wherein the direct voltage is in the range from 650 V to 700 V; and/or
wherein the DC voltage is 24 V or 48 V.

19. The automation platform of claim 12, wherein each of the functional modules provides a different function to the automation platform.
